(19) United States
(12) Patent Application Publication
(10) Pub. No.: US 2023/0281385 A1
(43) Pub. Date: Sep. 7, 2023

(54) FPGA-BASED FAST PROTOCOL DECODING METHOD, APPARATUS, AND DEVICE

(71) Applicant: INSPUR (BEIJING) ELECTRONIC INFORMATION INDUSTRY CO., LTD., Beijing (CN)

(72) Inventors: Guoqiang MEI, Beijing (CN); Rui HAO, Beijing (CN); Wei GUO, Beijing (CN)

(21) Appl. No.: 18/007,434

(22) PCT Filed: Feb. 19, 2021
(86) PCT No.: PCT/CN2021/076927

§ 371 Date: Jan. 30, 2023

(30) Foreign Application Priority Data
Jul. 30, 2020 (CN) 202010751254.2

(51) Int. Cl. G06F 40/221; G06F 40/14

(52) U.S. Cl. CPC G06F 40/221; G06F 40/14

(57) ABSTRACT

A field-programmable gate array (FPGA)-based FAST protocol decoding method, apparatus, and device, and a readable storage medium. The method acquires an actual XML template in real time and analyzes the actual XML template, generates a FAST protocol intermediate representation, and determines, according to preset decoding parameters, the maximum number of fields which are read at a single time, so as to generate a field matching state machine. Thus, the present disclosure can support a dynamically updated XML template, and allows flexible setting of the maximum number of fields according to an actual network bandwidth, and is applicable to disclosure scenarios of different network bandwidths. In a decoding process, the present disclosure realizes, by means of a field shift register and the field matching state machine, the function of reading and decoding a plurality of fields in parallel each time, significantly improving decoding efficiency.

### CROSS-REFERENCE TO RELATED APPLICATION

This disclosure claims priority to China Patent Application No. 202010751254.2, filed on Jul. 30, 2020 in China National Intellectual Property Administration and entitled “FPGA-based FAST Protocol Decoding Method, Apparatus and Device”, the entire contents of which are incorporated herein by reference.

### TECHNICAL FIELD

The present disclosure relates to the technical field of computers, in particular to a field-programmable gate array (FPGA)-based FAST protocol decoding method, apparatus and device, and a readable storage medium.

### BACKGROUND

The domestic Shanghai and Shenzhen LEVEL-2 market is transmitted using the FIX Adapted For Streaming (FAST) protocol. FAST is a message data stream-oriented coding method with high compression rate and processing efficiency. FAST coding includes using an Extensible Markup Language (XML) information template for encoding, variable-length coded byte compression and the like.

In the prior art, a FAST protocol decoding scheme includes three parts: reading data, decoding fields, and outputting a decoding result, and intermediate results are buffered through a buffer. A data reading component is responsible for reading a coded value of a field from a FAST market data input stream buffer. A field decoding component is responsible for specific decoding according to rules of field operators. A result outputting component is responsible for outputting a decoded field value to a FIX message buffer. However, in each operation of its core FAST field decoding, the encoded value of at most one field is read, which has limited performance and low decoding efficiency. Moreover, in practical applications, an XML template may need to be modified dynamically. In this case, a control logic needs to be modified. This scheme cannot be applied to the modified XML template.

It can be seen that how to provide a decoding scheme of a FAST protocol to avoid the defect that only one field can be decoded at a time and a dynamically updated XML template is not supported is the problem that need to be solved by those skilled in the art.

### SUMMARY

The present disclosure aims to provide a FPGA-based FAST protocol decoding method, apparatus, and device, and a readable storage medium, so as to solve the following problems: the current FAST protocol decoding scheme can decode only one field at a time and does not support a dynamically updated XML template, so that the decoding efficiency is low, and the scenario applicability is low. The specific method is as follows:

In a first aspect, the present disclosure provides the FPGA-based FAST protocol decoding method, including:
an Extensible Markup Language (XML) template of a FAST protocol is acquired, an existence condition of fields according to a structure of the XML template is determined, and according to a distribution of the fields in the XML template, a FAST protocol intermediate representation including the existence condition is generated;
a field matching state machine according to the FAST protocol intermediate representation and preset decoding parameters is generated, wherein the decoding parameters include the maximum number of fields processed in each clock cycle; the field matching state machine is configured to describe fields read at each time in the decoding process; the number of fields read at a single time is less than or equal to the maximum number of fields, and the existence conditions of the fields read at the same time are independent of each other;
a byte data stream of the FAST protocol by using an FPGA is received, the byte data stream into field data streams is segmented, and the field data streams to a field shift register are buffered; and
corresponding fields in parallel from the field shift register according to the field matching state machine are read, and the corresponding fields read in parallel from the field shift register are decoded.

In some embodiments, the existence condition of fields according to the structure of the XML template is the determined includes:
when a target field is in a cycle structure in the XML template, an existence relationship between the target field and a field is determined, prior to the target field, in the XML template, which is taken as an existence condition of the target field; and
when the target field is not in the cycle structure in the XML template, a target bit is determined, corresponding to the target field, in an existence bitmap field, which is taken as an existence condition of the target field;

In some embodiments, according to the distribution of the fields in the XML template, the FAST protocol intermediate representation including the existence condition is generated includes:
decoding properties of the fields according to the XML template are determined; and according to the distribution of the fields in the XML template, the FAST protocol intermediate representation including the existence conditions and the decoding properties is generated.

In some embodiments, the byte data stream into field data streams is segmented, and the field data streams to the field shift register are buffered includes:
the byte data stream into field data streams is segmented, and at each time of buffering, the fields with the maximum number of fields in parallel to the field shift register is buffered.

In some embodiments, corresponding fields in parallel from the field shift register according to the field matching state machine are read includes:
field matching according to the existence bitmap field is performed whether the various fields exist is determined, and corresponding fields in parallel from the field shift register according to the field matching state machine are read.

In some embodiments, the receiving a byte data stream of the FAST protocol by using the FPGA, segmenting the byte data stream into field data streams includes:
the byte data stream of the FAST protocol is received by using the FPGA, and the byte data stream into field data streams according to a stop bit is segmented.

In some embodiments, before the field matching state machine according to the FAST protocol intermediate representation and preset decoding parameters is generated, the method further includes:
a corresponding decoding parameter according to a current network bandwidth is determined.

In a second aspect, the present disclosure provides an FPGA-based FAST protocol decoding apparatus, including:
a template analysis module is configured to acquire an XML template of a FAST protocol, determine existence conditions of fields according to a structure of the XML template, and generate, according to a distribution of the fields in the XML template, a FAST protocol intermediate representation including the existence conditions;
a state machine generation module is configured to generate a field matching state machine according to the FAST protocol intermediate representation and preset decoding parameters, wherein the decoding parameters include the maximum number of fields processed in each clock cycle; the field matching state machine is configured to describe fields read at each time in the decoding process; the number of fields read at a single time is less than or equal to the maximum number of fields, and the existence conditions of the fields read at the same time are independent of each other;
a data stream segmentation module is configured to receive a byte data stream of the FAST protocol by using an FPGA, segment the byte data stream into field data streams, and buffer the field data streams to a field shift register; and
a decoding module is configured to read corresponding fields in parallel from the field shift register according to the field matching state machine, and decode the corresponding fields read in parallel from the field shift register.

In a third aspect, the present disclosure provides an FPGA-based FAST protocol decoding device, including:
a memory is configured to store a computer program; and
a processor is configured to execute the computer program to implement the steps of the above FPGA-based FAST protocol decoding device.

In a fourth aspect, the present disclosure provides a readable storage medium, wherein the readable storage medium stores a computer program; and the computer program, when executed by a processor, implements the steps of the above FPGA-based FAST protocol decoding device.

The FPGA-based FAST protocol decoding method provided by the present disclosure includes: the XML template of a FAST protocol is acquired, the existence condition of fields according to the structure of the XML template is determined, and according to the distribution of the fields in the XML template, the FAST protocol intermediate representation including the existence conditions is generated; the field matching state machine according to the FAST protocol intermediate representation and preset decoding parameters is generated, wherein the decoding parameters include the maximum number of fields processed in each clock cycle; the field matching state machine is configured to describe fields read at each time in the decoding process; the number of fields read at the single time is less than or equal to the maximum number of fields, and the existence conditions of the fields read at the same time are independent of each other; the byte data stream of the FAST protocol by using an FPGA is received, the byte data stream into field data streams is segmented, and the field data streams to the field shift register are buffered; and corresponding fields in parallel from the field shift register according to the field matching state machine are read, and the corresponding fields read in parallel from the field shift register are decoded.

To sum up, for the problems of low supportability for a dynamically updated XML template and failure of adapting to different network bandwidths at the present, by means of an actual XML template in real time is acquired and the actual XML template is analyzed, the FAST protocol intermediate representation is generated, and according to preset decoding parameters, the maximum number of fields is determined which are read at a single time, so as to generate a field matching state machine, the method can support a dynamically updated XML template, and allows flexible setting of the maximum number of fields according to an actual network bandwidth. In a decoding process, the method realizes a function of decoding a plurality of fields at a time by means of the field shift register and the field matching state machine. In an embodiment, after an input byte stream is segmented into fields, the fields are stored in the field shift register. The fields with the number less than or equal to the maximum number of fields are read in parallel at each time through the field matching state machine and are decoded, which significantly improves the decoding efficiency.

In addition, the present disclosure further provides the FPGA-based FAST protocol decoding apparatus and device, and the readable storage medium, the technical effects of which correspond to the technical effects of the above method, and descriptions thereof are omitted here.

### BRIEF DESCRIPTION OF THE DRAWINGS

In order to describe the embodiments of the present disclosure or the methods in the prior art more clearly, drawings required to be used in the embodiments or the illustration of the existing art will be briefly introduced below. Obviously, the drawings in the illustration below are only some embodiments of the present disclosure. Those ordinarily skilled in the art also can acquire other drawings according to the provided drawings without creative work.

FIG. 1 is a flow diagram of implementation of Embodiment I of an FPGA-based FAST protocol decoding method provided by the present disclosure;

FIG. 2 is a schematic diagram of a process of Embodiment I of the FPGA-based FAST protocol decoding method provided by the present disclosure;

FIG. 3 is a flow diagram of implementation of Embodiment II of an FPGA-based FAST protocol decoding method provided by the present disclosure;

FIG. 4 is a schematic diagram of a FAST protocol XML template UA3201 provided by the present disclosure;

FIG. 5 is a schematic diagram of binary data generated according to the XML template UA3201;

FIG. 6 is a detailed flow diagram of S302 in Embodiment II of the FPGA-based FAST protocol decoding method provided by the present disclosure;

FIG. 7 is a schematic diagram of a FAST protocol XML template UA3202 provided by the present disclosure;

FIG. 8 is a schematic diagram of one kind of feasible field matching state machine generated according to the XML template UA3202 provided by the present disclosure;

FIG. 9 is a schematic diagram of an overall process of Embodiment II of the FPGA-based FAST protocol decoding method provided by the present disclosure;

FIG. 10 is a schematic diagram of one kind of field matching state machine in a practical disclosure provided by the present disclosure; and

FIG. 11 is a functional block diagram of an embodiment of an FPGA-based FAST protocol decoding apparatus provided by the present disclosure.

### DETAILED DESCRIPTION OF THE EMBODIMENTS

In order to make those skilled in the art better understand the solutions of the present disclosure, the present disclosure is further described in detail below with reference to the accompanying drawings and specific implementation modes. Apparently, the described embodiments are merely a part of the embodiments of the present disclosure and not all the embodiments. Based on the embodiments in the present disclosure, all other embodiments obtained by those of ordinary skill in the art without creative work all fall within the protection scope of the present disclosure.

An existing FAST protocol decoding scheme has the following defects:

First, in a decoding process, only one field can be read at a time. In a common network interface with a bandwidth of 10 G, an input FAST data stream often contains four fields at most. It can be seen that the existing FAST decoding scheme cannot give full play to the bandwidth advantage.

Second, there is a possibility of dynamic update of an XML template in the financial field. In the existing FAST decoding scheme, new decoding operators are manually mounted, and a control logic of a controller needs to be modified, so it takes a long time to modify and verify the control logic, and the update cannot be completed at the first time. It can be seen that the existing FAST decoding scheme does not support a dynamically updated XML template.

Third, for network interfaces with different kinds of bandwidths, including 1G/10G/25G/40G/100G, the existing FAST decoding scheme uses the same decoding method, which cannot flexibly adapt to different network bandwidths.

For the above problems, the present disclosure provides the FPGA-based FAST protocol decoding method, apparatus and device, and the readable storage medium. The method acquires an actual XML template in real time and analyzes the actual XML template, determines, according to preset decoding parameters, the maximum number of fields which are read at a single time, so as to generate a field matching state machine. Thus, the present disclosure can support a dynamically updated XML template, and allows flexible setting of the maximum number of fields according to an actual network bandwidth. Furthermore, after the input byte stream is segmented into the fields, the fields are stored in the field shift register. The fields with the number less than or equal to the maximum number of fields are read in parallel at each time through the field matching state machine and are decoded, which significantly improves the decoding efficiency.

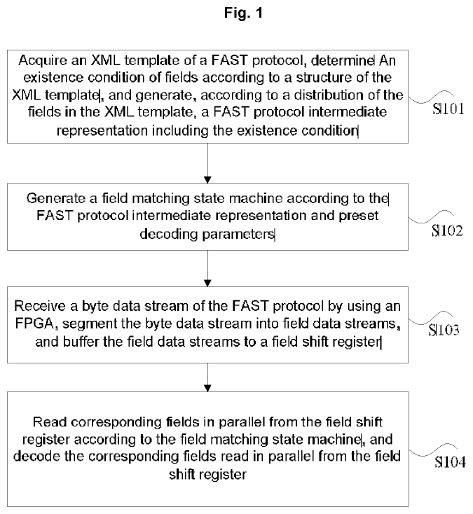

Embodiment I of the FPGA-based FAST protocol decoding method provided by the present disclosure is described below. Referring to FIG. 1, Embodiment I includes:

At step S101, an XML template of a FAST protocol is acquired; an existence condition of fields is determined according to a structure of the XML template; and a FAST protocol intermediate representation including the existence condition is generated according to a distribution of the fields in the XML template.

At step S102, a field matching state machine is generated according to the FAST protocol intermediate representation and preset decoding parameters.

At step S103, a byte data stream of the FAST protocol is received by using an FPGA; the byte data stream is segmented into field data streams; and the field data streams are buffered to a field shift register.

At step S104, corresponding fields are read in parallel from the field shift register according to the field matching state machine, and the corresponding fields read in parallel from the field shift register are decoded.

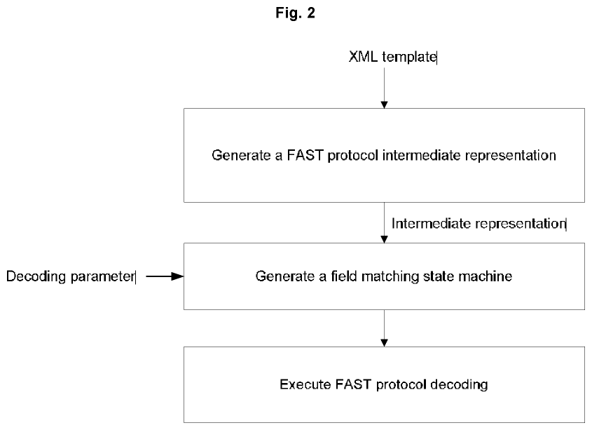

The overall framework of this embodiment is as shown in FIG. 2, mainly including three parts:

The first part is to generate the FAST protocol intermediate representation. The XML template of the FAST protocol is first read, and the structure of the XML template is analyzed to determine the existence condition of the various fields in the XML template; and the FAST protocol intermediate representation is generated according to the distribution of the fields in the XML template. In this embodiment, the FAST protocol intermediate representation contains the existence conditions of the fields.

The above existence conditions are used for describing a relationship between the existence of each FAST field and the previously received FAST field. In an embodiment, in practical applications, the existence of a field in the XML template may not be affected by other fields, or may be affected by an actual value of a field in front of this field. For these two cases, this embodiment describes the existence condition of each field.

The second part is to generate the field matching state machine of the FAST protocol. The field matching state machine is generated according to the FAST protocol intermediate representation and the preset decoding parameters. Wherein, the decoding parameters include the following information: the maximum number of fields processed in clock cycle. The field matching state machine is configured to describe fields read at each time in the decoding process, and satisfies the following conditions: the number of fields read at the single time is less than or equal to the maximum number of fields, and the existence conditions of the fields read at the same time are independent of each other.

Wherein, the decoding parameter refers to the maximum number of fields processed in each clock cycle. A specific value can be configured according to an actual application scenario, which can be 4, 8, 16, 32, 64 and other configurations. This embodiment does not limit the specific value.

Each existence conditions is independent of each other, so that whether a current field has this situation is not affected by other fields.

The main purpose of this part is to optimize FPGA parallelization and minimize an FPGA processing delay and processing logic. In an embodiment, the field matching state machine is configured to describe a certain number of fields that can be read in each reading process and have independent existence conditions, so as to achieve the purpose of reading multiple fields in parallel at each time and improve the decoding efficiency. As a preferred implementation, the field matching state machine can describe the maximum number of fields that can be read in each reading process and have independent existence conditions. It can be understood that the maximum number here also needs to satisfy the conditions of being less than or equal to the maximum number of fields mentioned above.

The third part is to segment and decode the byte data stream of the FAST protocol.

In an embodiment, a register transfer level (RTL) decoding code can be generated according to the foregoing field matching state machine, and then the whole decoding flow can be realized by running the RTL decoding code.

This embodiment provides the FPGA-based FAST protocol decoding method. The current problem of decoding at most one field at a time is solved by the field shift register and the field matching state machine. After the input byte stream is divided into the fields, the fields are stored in the field shift register, and the field matching state machine dynamically reads variable fields to achieve the processing ability of decoding multiple fields at a time, which significantly improves the decoding efficiency. For the problems that the current system has low supportability for dynamic template update and fails in adapting to different network bandwidths, in the process of generating the field matching state machine, the actual XML template is acquired in real time and the actual XML template is analyzed, and the maximum number of fields which are read at the single time is determined according to the preset decoding parameters, so as to generate a field matching state machine. Therefore, the method can support a dynamically updated XML template, and allows flexible setting of the maximum number of fields according to an actual network bandwidth.

To sum up, this embodiment at least includes the following advantages:
advantage 1, dynamic update of the XML template is supported;
advantage 2, the decoding logic supports decoding multiple fields in parallel at each time, which improves the decoding performance; and
advantage 3, the decoding logic supports various network bandwidths, and is highly flexibly configurable, which fully exerts the advantages of the network bandwidths.

The following is a detailed description of Embodiment II of the FPGA-based FAST protocol decoding method provided in the present disclosure. Embodiment II is implemented on the basis of above Embodiment I, and has been expanded to a certain extent on the basis of Embodiment I.

In an embodiment, this embodiment describes in detail the process of determining the existence conditions of the fields. This embodiment also uses a parallel buffering manner in the buffering process, such as buffering with the current maximum number of fields. In addition, this embodiment can automatically set a corresponding decoding parameter according to a current network bandwidth.

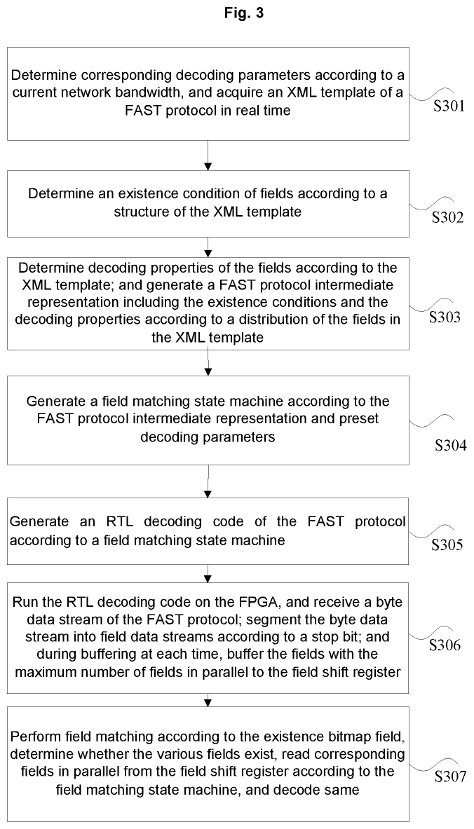

Referring to FIG. 3, in an embodiment, Embodiment II includes:

At step S301, the corresponding decoding parameter is determined according to a current network bandwidth, and an XML template of the FAST protocol is acquired in real time.

At step S302, existence conditions of fields are determined according to the structure of the XML template.

At step S303, decoding properties of the fields are determined according to the XML template; and a FAST protocol intermediate representation including the existence conditions and the decoding properties is generated according to the distribution of the fields in the XML template.

At step S304, the field matching state machine is generated according to the FAST protocol intermediate representation and preset decoding parameters.

At step S305, the RTL decoding code of the FAST protocol is generated according to the field matching state machine.

At step S306, the RTL decoding code is run on the FPGA, and the byte data stream of the FAST protocol is received; the byte data stream is segmented into field data streams according to the stop bit; and during buffering at each time, the fields with the maximum number of fields are buffered in parallel to the field shift register.

At step S307, field matching is performed according to the existence bitmap field; whether the various fields exist is determined; corresponding fields are read in parallel from the field shift register according to the field matching state machine, and the corresponding fields read in parallel from the field shift register are decoded.

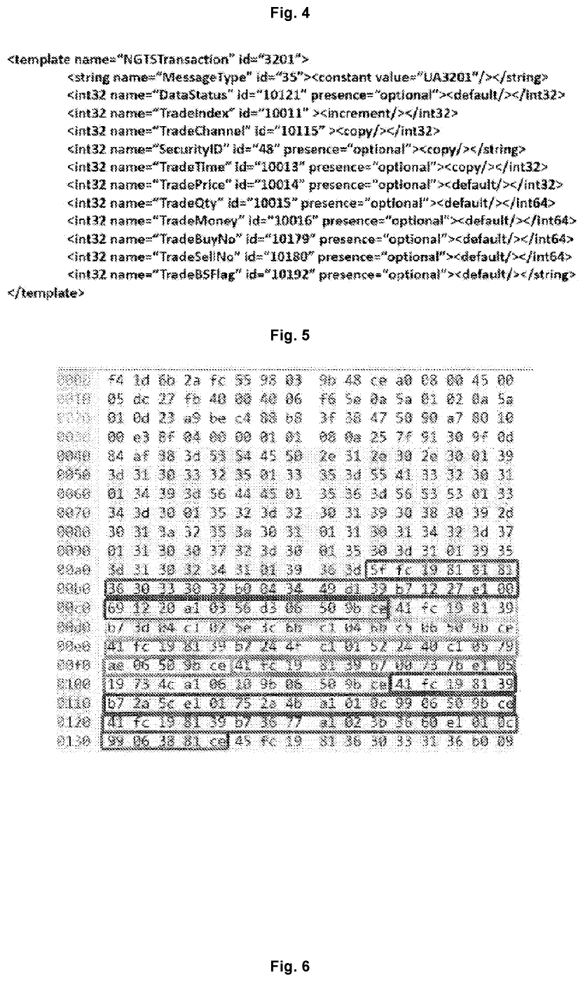

A typical FAST protocol XML template UA3201 is shown in FIG. 4. Each line of the XML template is used for describing one field, including key elements such as the type, name, ID number and operator of the field. The field is subjected to variable-length coding and compression, and can be segmented by taking the stop bit as a delimiter.

After coding is performed according to the template, binary data received by an actual market is as shown in FIG. 5. Two adjacent fields are divided by the stop bit, that is, the highest bit of 1 of the byte. In FIG. 5, the first few fields are 5ffc, 1981, 81, 81, 3630333032b0, and the like. The first field is usually an existence bitmap field, which determines which specific field in the template will be transmitted later. For example, 5ffc, i.e. 0101_ 1111_ 1111_ 1100, means that the existence bitmap field after decoding is 1011111_ 1111100 (the highest bits of two bytes are rounded off). The existence bitmap field is used for checking whether the various fields described in the XML template exist. In an embodiment, the existence bitmap field here indicates that TemplateID (Message Type) exists, DataStatus does not exist, and TradeIndex, TradeChannel, SecurityID, TradeTime, TradePrice, TradeQuality, TradeMoney, TradeBuyNo, TradeSellNo, and TradeBSFlag exist. Since the XML template shown in FIG. 4 has only 12 fields, the last two bits, i.e. 0, of the existence bitmap field are padding bytes bit, which have no practical significance.

During the generation of the intermediate representation, this embodiment first reads the XML template of the FAST protocol, analyzes the structure of the XML template, and finally generates the FAST protocol intermediate representation according to whether the structure contains an internal cycle, the existence conditions and decoding properties of the various fields, and the configured FAST decoding parameters. Therefore, as shown in FIG. 6, S302 above includes:

At step S601, when a target field is in a cycle structure in the XML template, it is determined that the target field has an existence relationship with a field, prior to the target field, in the XML template, which is taken as an existence condition of the target field; and

At step S602, when the target field is not in the cycle structure in the XML template, a target bit, corresponding to the target field, in an existence bitmap field is determined, which is taken as an existence condition of the target field.

For example, the FAST protocol intermediate representation corresponding to the XML template UA3201 is as follows, which describes the following information: The existence of each field is determined by a certain bit of the existence bitmap field:
TIDreg_pmap[0]
DataStatusreg_pmap[1]
TradeIndexreg_pmap[2]
TradeChannelreg_pmap[3]
SecurityIDreg_pmap[4]
TradeTimereg_pmap[5]
TradePricereg_pmap[6]
TradeQtyreg_pmap[7]
TradeMoneyreg_pmap[8]
TradeBuyNoreg_pmap[9]
TradeSellN,reg_pmap[10]
TradeBSFlagreg_pmap[11]

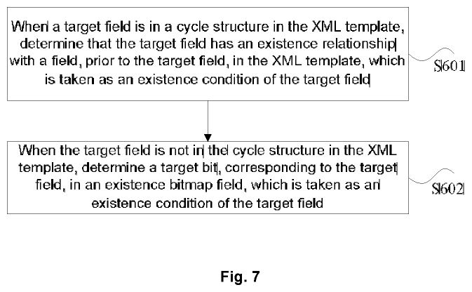

A fragment of the XML template UA3202 of FIG. 7 is taken as an example. The template has the cycle structure. Some relatively fixed parts at the beginning are omitted. In the cycle structure, the corresponding part of the FAST protocol intermediate representation is as follows. This part of FAST protocol intermediate representation describes the following information: a relationship between the existence of each field and a field received before:
Orders(BidLevels>0&&NoOrders>0)
OrderQueueOperator(BidLevels>0&&NoOrders>0&&ImageStatus=2)
OrderQueueOperatorEntryID(BidLevels>0&&NoOrders>0&&ImageStatus=2&&OrderQueueOperator==2 or 3)
OrderQty(BidLevels>0&&NoOrders>0&&ImageStatus=2&&OrderQueueOperator !=3)

For the relatively simple XML template of the FAST protocol, such as UA3201 shown in FIG. 4, the existence of its fields only depends on the existence bitmap field. For the relatively complex XML template of the FAST protocol, such as UA3202 shown in FIG. 7, the existence of its fields depends not only on the existence bitmap field, but also on actual values of other fields. Therefore, in order to minimize the complexity of receiving a matching state machine and meet the requirements of input field processing ability parameters, the field matching state machine needs to be generated according to the FAST protocol intermediate representation.

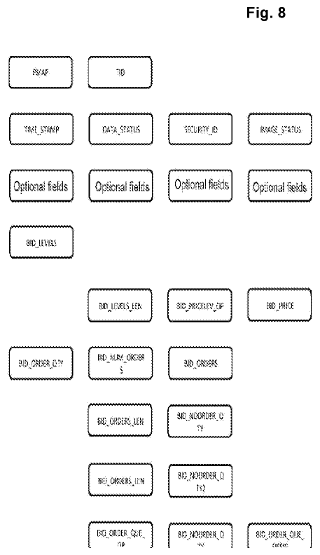

Assuming that the maximum number of fields allowed by the current network bandwidth is four, the template UA3202 shown in FIG. 7 is taken as an example, a feasible field matching state machine is as shown in FIG. 8. Each line of FIG. 8 is one state of the field matching state machine. The number of fields on each line does not exceed the preset maximum number of fields, that is, the number of fields on each line does not exceed four. In FIG. 8, fourth line represents the beginning of a large cycle, and sixth line represents the beginning of a sub-cycle of the large cycle. Similarly, tenth line represents the beginning of another large cycle, and twelfth line represents the beginning of a sub-cycle of this large cycle.

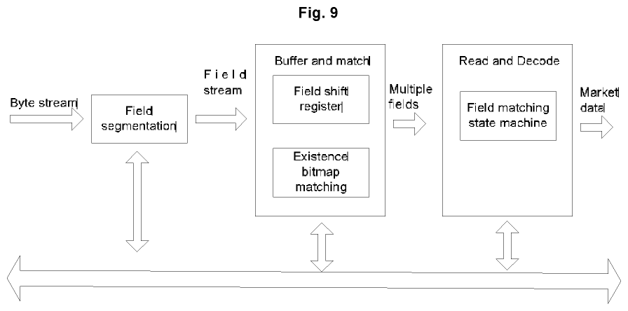

When the FPGA is used for decoding the FAST protocol, the input byte data stream is first segmented into field data streams according to the stop bit and buffered in the field shift register. The fields are dynamically matched according to the existing bitmap field of the XML template. The corresponding fields are read in parallel from the field shift register and are decoded to obtain FAST market data. The whole decoding flow is as shown in FIG. 9.

It can be seen that this embodiment provides an FPGA-based FAST protocol decoding method, marked features of which include:

First, the FAST protocol intermediate representation is generated. First, the XML template of the FAST protocol is generated; a network structure of the FAST protocol is analyzed; and the FAST protocol intermediate representation format is generated according to whether the network structure contains an internal cycle, the existence and decoding properties of the various fields, and the configured FAST decoding parameters.

Second, the field matching state machine of the FAST protocol is generated. FPGA parallelization optimization is performed according to the FAST protocol intermediate representation and the FAST decoding parameters; the FPGA processing delay and processing logic are minimized, thus obtaining the field matching state machine of the FAST protocol.

Third, the RTL decoding code of the FAST protocol is generated, and the data stream of the FAST protocol is decoded by running the RTL decoding code.

In practical disclosures, the FAST market data may contain gear cycle data and commission cycle data in two directions of buying and selling. When decoding is performed according to the number of input fields, a jump relationship is too complex. In order to reduce the complexity of field matching, the present disclosure buffers the input fields to the field shift register, wherein the number of input fields in the shift register is the maximum number of fields in each clock cycle. For example, when four bytes are input in the case of 10 Gbits/s, the bytes correspond to at most four fields. An output of the shift register is the number of fields read by the field matching state machine. Both the throughput and design clock frequency are taken into consideration, and at most four fields are read. The field matching state machine simplifies the number of states of the matching state machine and increases the clock frequency by limiting the jump of a FAST decoding state. At the same time, the overall throughput is improved by obtaining the number of parallel fields.

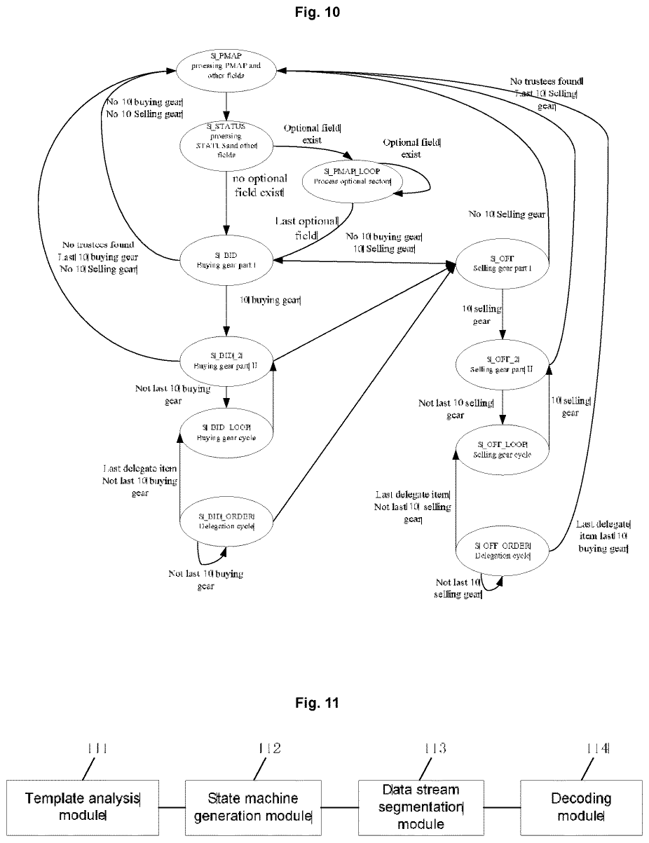

The specific jump of the matching state machine jump is as shown in FIG. 10. As shown in FIG. 10, in the present disclosure, the matching state machine is changed from the traditional field-by-field jump to the matching jump of multiple parallel fields, which improves the ability of processing multiple fields in a single clock. At the same time, the jump between state machines is optimized. Instead of simple jump according to the number of input fields, the complexity of the state machine is simplified on the premise of reading fields as many as possible by limiting the jump possibility of the state machine in advance and dynamically reading multiple parallel fields according to known information.

Based on the above two features, the present disclosure reduces the number of cycles that FAST data needs to be processed, and increases the dominant frequency of the matching state machine, thus reducing the overall processing delay.

The following is a description of an FPGA-based FAST protocol decoding apparatus provided by an embodiment of the present disclosure. The FPGA-based FAST protocol decoding apparatus described below can refer to the FPGA-based FAST protocol decoding method described above.

As shown in FIG. 11, the FPGA-based FAST protocol decoding apparatus of this embodiment includes:
a template analysis module 111 is configured to acquire an XML template of a FAST protocol, determine an existence condition of fields according to a structure of the XML template, and generate, according to a distribution of the fields in the XML template, a FAST protocol intermediate representation including the existence conditions;
a state machine generation module 112 is configured to generate a field matching state machine according to the FAST protocol intermediate representation and preset decoding parameters, wherein the decoding parameters include the maximum number of fields processed in each clock cycle; the field matching state machine is configured to describe fields read at each time in the decoding process; the number of fields read at a single time is less than or equal to the maximum number of fields, and the existence conditions of the fields read at the same time are independent of each other;
a data stream segmentation module 113 is configured to receive a byte data stream of the FAST protocol by using an FPGA, segment the byte data stream into field data streams, and buffer the field data streams to a field shift register; and a decoding module 114 is configured to read corresponding fields in parallel from the field shift register according to the field matching state machine, and decode the corresponding fields read in parallel from the field shift register.

The FPGA-based FAST protocol decoding apparatus of this embodiment is configured to implement the aforementioned FPGA-based FAST protocol decoding method. Therefore, the specific implementation of this apparatus can refer to the embodiment of the FPGA-based FAST protocol decoding method mentioned above. For example, the template analysis module 111, the state machine generation module 112, the data stream segmentation module 113, and the decoding module 114 are respectively configured to implement steps S101, S102, S103 and S104 of the above FPGA-based FAST protocol decoding method. Therefore, the FPGA-based FAST protocol decoding apparatus's specific implementations can refer to the descriptions of the embodiments of the corresponding parts and will not be described here.

In addition, since the FPGA-based FAST protocol decoding device of this embodiment is configured to implement the aforementioned FPGA-based FAST protocol decoding method. Therefore, the function corresponds to that of the above method, which will not be repeated here.

In addition, the present disclosure further provides an FPGA-based FAST protocol decoding device, including:
a memory is configured to store a computer program; and
a processor is configured to execute the computer program to implement the steps of the above FPGA-based FAST protocol decoding device.

Finally, the present disclosure provides the readable storage medium. The readable storage medium stores a computer program; and the computer program, when executed by a processor, implements the steps of the above FPGA-based FAST protocol decoding device.

All the embodiments in this specification are described in a progressive manner. Contents mainly described in each embodiment are different from those described in other embodiments. Same or similar parts of all the embodiments refer to each other. For the device disclosed in the embodiments, since it corresponds to the method disclosed in the embodiments, the description is relatively simple, and the relevant part can be referred to the description of the method part.

The steps of a method or algorithm described in conjunction with the embodiments disclosed herein may be directly implemented in hardware, a software module executed by a processor, or a combination of the hardware and the software module. The software module can be placed in a random access memory (RAM), an internal memory, a read only memory (ROM), an electrically programmable ROM, an electrically erasable programmable ROM, a register, a hard disk, a mobile disk, a CD-ROM, or any storage medium in other forms known to the technical field.

The above describes the solutions provided by the present disclosure in detail. Specific examples are used herein to illustrate the principle and implementation modes of the present disclosure. The descriptions of the above embodiments are only used to help understand the method and its key thoughts of the present disclosure. Moreover, for those of ordinary skill in the art, according to the ideas of the present disclosure, there will be changes in the specific implementation modes and the scope of disclosure. In summary, the content of this specification should not be construed as limiting the present disclosure.

1. A field-programmable gate array (FPGA)-based FAST protocol decoding method, comprising:
acquiring an Extensible Markup Language (XML) template of a FAST protocol, determining an existence condition of fields according to a structure of the XML template, and generating, according to a distribution of the fields in the XML template, a FAST protocol intermediate representation comprising the existence condition;
generating a field matching state machine according to the FAST protocol intermediate representation and preset decoding parameters, wherein the decoding parameters comprise the maximum number of fields processed in each clock cycle;
the field matching state machine is configured to describe fields read at each time in the decoding process; the number of fields read at a single time is less than or equal to the maximum number of fields, and the existence conditions of the fields read at the same time are independent of each other;
receiving a byte data stream of the FAST protocol by using an FPGA, segmenting the byte data stream into field data streams, and buffering the field data streams to a field shift register; and
reading corresponding fields in parallel from the field shift register according to the field matching state machine, and decoding the corresponding fields read in parallel from the field shift register.

2. The method as claimed in claim 1, wherein determining existence condition of fields according to the structure of the XML template comprises:
when a target field is in a cycle structure in the XML template, determining an existence relationship between the target field and a field, prior to the target field, in the XML template, which is taken as an existence condition of the target field; and
when the target field is not in the cycle structure in the XML, template, determining a target bit, corresponding to the target field, in an existence bitmap field, which is taken as an existence condition of the target field.

3. The method as claimed in claim 2, wherein generating, according to the distribution of the fields in the XML template, the FAST protocol intermediate representation comprising the existence condition comprises:
determining decoding properties of the fields according to the XML template; and
generating, according to the distribution of the fields in the XML template, the FAST protocol intermediate representation comprising the existence condition and the decoding properties.

4. The method as claimed in claim 1, wherein segmenting the byte data stream into field data streams, and buffering the field data streams to the field shift register comprises:
segmenting the byte data stream into field data streams, and at each time of buffering, buffering the fields with the maximum number of fields in parallel to the field shift register.

5. The method as claimed in claim 1, wherein reading corresponding fields in parallel from the field shift register according to the field matching state machine comprises:
performing field matching according to the existence bitmap field, determining whether the various fields exist, and reading corresponding fields in parallel from the field shift register according to the field matching state machine.

6. The method as claimed in claim 1, wherein receiving the byte data stream of the FAST protocol by using the FPGA, segmenting the byte data stream into field data streams comprises:
receiving the byte data stream of the FAST protocol by using the FPGA, and segmenting the byte data stream into field data streams according to a stop bit.

7. The method as claimed in claim 1, wherein before the field matching state machine is generated according to the FAST protocol intermediate representation and preset decoding parameters, the method further comprises:
determining a corresponding decoding parameter according to a current network bandwidth.

8. (canceled)

9. A FPGA-based FAST protocol decoding device, comprising:
a memory, configured to store a computer program; and
a processor, configured to execute the computer program to:
acquire an Extensible Markup Language (XML) template of a FAST protocol, determine an existence condition of fields according to a structure of the XML template, and generate, according to a distribution of the fields in the XML template, a FAST protocol intermediate representation comprising the existence condition;
generate a field matching state machine according to the FAST protocol intermediate representation and preset decoding parameters, wherein the decoding parameters comprise the maximum number of fields processed in each clock cycle;
the field matching state machine is configured to describe fields read at each time in the decoding process; the number of fields read at a single time is less than or equal to the maximum number of fields, and the existence conditions of the fields read at the same time are independent of each other;
receive a byte data stream of the FAST protocol by using an FPGA, segment the byte data stream into field data streams, and buffer the field data streams to a field shift register; and
read corresponding fields in parallel from the field shift register according to the field matching state machine, and decode the corresponding fields read in parallel from the field shift register.

10. A readable storage medium, wherein the readable storage medium stores a computer program; and the computer program, when executed by a processor, cause the processor to:
acquire an Extensible Markup Language (XML) template of a FAST protocol, determine an existence condition of fields according to a structure of the XML template, and generate, according to a distribution of the fields in the XML template, a FAST protocol intermediate representation comprising the existence condition;
generate a field matching state machine according to the FAST protocol intermediate representation and preset decoding parameters, wherein the decoding parameters comprise the maximum number of fields processed in each clock cycle;
the field matching state machine is configured to describe fields read at each time in the decoding process; the number of fields read at a single time is less than or equal to the maximum number of fields, and the existence conditions of the fields read at the same time are independent of each other;
receive a byte data stream of the FAST protocol by using an FPGA, segment the byte data stream into field data streams, and buffer the field data streams to a field shift register; and
read corresponding fields in parallel from the field shift register according to the field matching state machine, and decode the corresponding fields read in parallel from the field shift register.

11. The method as claimed in claim 1, wherein generating the field matching state machine according to the FAST protocol intermediate representation and preset decoding parameters comprises:
determining the maximum number of fields which are read at the single time according to the preset decoding parameters; and
generating the field matching state machine according to the FAST protocol intermediate representation and the maximum number of fields.

12. The method as claimed in claim 1, wherein before the byte data stream of the FAST protocol by using the FPGA is received, the method further comprises:
generating a register transfer level (RTL) decoding code of the FAST protocol according to the field matching state machine.

13. The method as claimed in claim 12, wherein receiving the byte data stream of the FAST protocol by using the FPGA comprises:
running the RTL decoding code on the FPGA; and
receiving the byte data stream of the FAST protocol by using the FPGA.

14. The method as claimed in claim 1, wherein reading corresponding fields in parallel from the field shift register according to the field matching state machine comprises:
reading fields with the number less than or equal to the maximum number of fields in parallel at each time through the field matching state machine; and
decoding the fields with the number less than or equal to the maximum number of fields in parallel through the field matching state machine.

15. The method as claimed in claim 1, wherein determining the existence condition of fields according to the structure of the XML template comprises:
reading the XML, template of the FAST protocol; and
determining the existence condition of the fields in the XML template through analyzing the structure of the XML template.

16. The method as claimed in claim 1, wherein the existence condition is used for describing a relationship between the existence of each field and the previously received field.

17. The FPGA-based FAST protocol decoding device as claimed in claim 9, the processor is further configured to execute the computer program to:
when a target field is in a cycle structure in the XML template, determine an existence relationship between the target field and a field, prior to the target field, in the XML template, which is taken as an existence condition of the target field; and
when the target field is not in the cycle structure in the XML, template, determine a target bit, corresponding to the target field, in an existence bitmap field, which is taken as an existence condition of the target field.

18. The FPGA-based FAST protocol decoding device as claimed in claim 17, the processor is further configured to execute the computer program to:
determine decoding properties of the fields according to the XML template; and
generate, according to the distribution of the fields in the XML template, the FAST protocol intermediate representation comprising the existence condition and the decoding properties.

19. The FPGA-based FAST protocol decoding device as claimed in claim 9, the processor is further configured to execute the computer program to:
segment the byte data stream into field data streams, and at each time of buffering, buffer the fields with the maximum number of fields in parallel to the field shift register.

20. The FPGA-based FAST protocol decoding device as claimed in claim 9, the processor is further configured to execute the computer program to:
perform field matching according to the existence bitmap field, determine whether the various fields exist, and read corresponding fields in parallel from the field shift register according to the field matching state machine.

21. The FPGA-based FAST protocol decoding device as claimed in claim 9, the processor is further configured to execute the computer program to:
receive the byte data stream of the FAST protocol by using the FPGA, and segment the byte data stream into field data streams according to a stop bit.
